(19) United States
(12) Patent Application Publication
(10) Pub. No.: US 2007/0028667 A1
(43) Pub. Date: Feb. 8, 2007

(54) Electronic nose sensor array, sensor system including the same, method of manufacturing the same, and analysis method using the sensor system

(75) Inventors: Yong Shin Kim, Daejeon-city (KR); Yoon Seok Yang, Daejeon-city (KR); Seung Chul Ha, Gyeonggi-do (KR); Tae Hwan Yoon, Gyeonggi-do (KR); Hyeon Bong Pyo, Daejeon-city (KR); Chang Auck Choi, Daejeon-city (KR)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(73) Assignee: Electronics and Telecommunications Research Institute

(21) Appl. No.: 11/363,797

(22) Filed: Feb. 27, 2006

(30) Foreign Application Priority Data
Aug. 8, 2005 (KR) 10-2005-0072325

(51) Int. Cl. G01N 27/12; G01R 3/00

(52) U.S. Cl. 73/23.34; 702/31; 29/595

(57) ABSTRACT

Provided are an electronic nose sensor array which can easily measure and process a sample using a personal information terminal and can be mass-produced, a sensor system including the same, a method of manufacturing the electronic nose sensor array, and a analysis method using the electronic nose sensor system. The sensor array comprises a plurality of sensing films which are formed on a side of a polymer substrate and react to chemical species to be analyzed, thereby changing their electric resistances, and a plurality of sensing electrodes, each of which contacts both ends of each of the sensing films and senses a change of one of the electric resistances.

### CROSS-REFERENCE TO RELATED PATENT APPLICATIONS

This application claims the priority of Korean Patent Application No. 10-2005-0072325, filed on Aug. 8, 2005, in the Korean Intellectual Property Office, the disclosure of which is incorporated herein in its entirety by reference.

### BACKGROUND OF THE INVENTION

1. Field of the Invention

The present invention relates to an electronic nose sensor array, and more particularly, to an electronic nose sensor array using a plurality of chemical sensors having non-specific sensing characteristics, a sensor system including the electronic nose sensor array, a method of manufacturing the sensor array, and an analysis method using the sensor system.

2. Description of the Related Art

Generally, instrumentation such as gas chromatographs and spectrographs are used to identify chemical species in a gaseous state. Recently, compact portable devices are used to analyze chemical species. Thus, air pollution, infections due to harmful microorganisms, and contaminations due to chemical, biological, and radiological materials can be detected in real-time using portable analysis devices. However, the performance of theses portable analysis devices deteriorates as they are miniaturized, and also it takes too much time to analyze complex chemical compounds. To solve the above problems, portable analysis devices using small chemical sensor array are actively being developed. In particular, to detect various chemical species, electronic nose system in which a plurality of chemical sensors are arrayed are being developed.

An electronic nose sensor array may include an oxide semiconductor element typically made of SnO₂, a quartz crystal microbalance (QCM) using a bulk acoustic wave, a surface acoustic wave (SAW) element using an SAW, a conductive polymer element, a polymer composite element comprising conductive particles and non-conductive polymers, and a colorimetric analysis element using a change in an absorption wavelength of a single molecule. Among the above elements, the conductive polymer element and the polymer composite element are widely used. A sensor array using a polymer is advantageous in that various sensors can be manufactured and mass production can be easily achieved.

However, the sensor array using a polymer is sensitive to temperature and humidity because the polymer is organic in nature. Accordingly, this sensor array should be used in constant temperature and humidity conditions. Specifically, the conductive polymer element and polymer composite element using an organic polymer can operate at normal temperature, but the sensing characteristics vary with the temperature. Thus, a constant temperature condition should be satisfied to obtain an unchanging sensing pattern. Conventionally, to ensure a constant temperature, a ceramic substrate having a resistance heater using fine metal wires is widely used. There is, however, a great amount of heat loss from the ceramic substrate to the outside, which causes a compact electronic nose sensor to consume too much power.

U.S. Pat. No. 6,418,783 discloses an electronic nose sensor which is configured to be a desk-top sensor or a hand-held sensor based on several sensor techniques and a spectrograph. Moreover, efforts are continuously being made to miniaturize such electronic nose sensors. For example, software capable of processing a sensing result in real-time in a handheld or PDA environment has been introduced by H. T. Cheuh et al., “Sensors and Actuators B 83”, p. 262, 2002, and a software environment capable of recognizing a pattern by effectively minimizing computational load in a small microprocessor has been provided by A. Perera, IEEE Sensors Journal 2, p. 235, 2002.

However, up to now, a compact complete electronic nose sensor which can be attached to a personal portable information terminal (hereinafter referred to as a ‘personal information terminal’) such as a personal digital assistant (PDA) has not yet been developed. That is, there is no technology to mass produce a compact electronic nose sensor having low power consumption. Furthermore, there is no simple sample analysis method proper for a compact sensor, and difficulties for obtaining and processing data in a personal information terminal has not been yet solved.

### SUMMARY OF THE INVENTION

The present invention provides an electronic nose sensor array and sensor system which can easily measure and process a sample and be mass-produced.

The present invention also provides a method of manufacturing an electronic nose sensor array which can easily measure and process a sample and be mass-produced and an analysis method using an electronic nose sensor system.

According to an aspect of the present invention, there is provided an electronic nose sensor array comprising: a flat-panel type polymer substrate; a plurality of sensing films which is formed on a first side of the polymer substrate and react to chemical species to be analyzed, thereby changing their electric resistances; and a plurality of sensing electrodes, each of which contacts both ends of each of the sensing films and senses a change of one of the electric resistances.

The polymer substrate may be at least one selected from polyimide, polyester, and glass epoxy.

The sensing film may be made of a mixture of conductive particles and non-conductive organic material. The sensing film may operate at a normal temperature. The sensing film may be made of a mixture of conductive carbon black and polymer.

The non-conductive organic material is at least one selected from Polystyrene, Poly(methyl methacrylate), Polyvinylpyrrolidone, Poly(vinyl acetate), Poly(ethylene oxide), Poly(-methylstyrene), Poly(4-vinylphenol), Polysulfone, Polycaprolactone, Poly(4-methylstylene), Poly(stylene-co-methylmethacrylate), Poly(ethylene-co-vinylacetate), Poly(vinylidene chloride-co-acrylonitrile), Poly(styrene-co-allyl alcohol), Poly(methyl vinyl ether-alt-maleic anhydride), Poly(styrene-co-butadiene), Poly(bisphenol A carbonate), Poly(butadiene), Poly(4-vinyl pyridine), Poly(styrene-co-maleic anhydride), Poly(styrene-co-acrylonitrile), Poly(ethylene-co-acrylic acid), Poly(vinyl chloride-co-vinyl acetate), Poly(vinyl butyral)-co-vinyl alcohol-co-vinyl acetate, Poly(vinyl stearate), Ethyl cellulose, Polystrene-black-polyisoprene-black-polystrene, Hydroxypropyl cellulose, Cellulose acetate, and Poly(ethylene glycol).

The sensing electrodes may be parts of an upper metal line exposed by an upper protecting layer.

A fine heater may be disposed on a second side of the polymer substrate, and a lower protecting layer may cover the fine heater to block the fine heater from the outside.

According to another aspect of the present invention, there is provide a electronic nose sensor system comprising: a electronic nose sensor array; and a personal digital assistant to which the electronic nose sensor array is attached and which obtains data measured by the electronic nose sensor array in real-time and processes the data using a pattern recognition program, wherein the electronic sensor array comprises: a flat-panel type polymer substrate; a plurality of sensing films which is formed on a side of the polymer substrate and react to chemical species to be analyzed, thereby changing their electric resistances; and a plurality of sensing electrodes, each of which contacts both ends of each of the sensing films and senses a change of one of the electric resistances.

The pattern recognition program may be a principal component analysis method.

The personal digital assistant may include an electronic circuit board that digitalizes and transmits the measured data to the personal digital assistant. The electronic circuit board may comprise an analog/digital convert and a digital bus interface.

The electronic nose sensor array may further comprise hardware for extracting a sample. The hardware for extracting sample may include a liquid permeative film which allows the sample to evaporate and causes the concentration gradient.

According to another aspect of the present invention, there is provided a method of manufacturing an electronic nose sensor array, the method comprising: preparing a polymer substrate; forming an upper metal line on a side of the polymer substrate, the upper metal line including a plurality sensing electrodes and contact pads; forming a plurality of heaters on the opposite side of the polymer substrate; and forming a plurality of sensing films made of a mixture of conductive particles and a non-conductive material.

The upper metal line and the heaters may be formed using an electrochemical deposition. The sensing electrodes may be interlaced with each other, each having a comb shape.

According to another aspect of the present invention, there is provided a method of analyzing a sample using an electronic nose sensor array, the method comprising: extracting a sample using hardware for extracting the sample; starting measuring the sample using a personal digital assistant employing a pattern recognition program; attaching the hardware for extracting the sample to a sensor array support; saturating reactions in the electronic nose sensor array; separating the hardware for extracting the sample from the sensor array support; and initializing the reactions in the electronic nose sensor array, wherein the electronic nose sensor array comprises: a flat-panel type polymer substrate; a plurality of sensing films which is formed on a side of the polymer substrate and react to chemical species to be analyzed, thereby changing their electric resistances; and a plurality of sensing electrodes, each of which contacts both ends of each of the sensing films and senses a change of one of the electric resistance.

The hardware for extracting the sample may comprise a sample extraction plate formed by a liquid permeative film and a sample plate support, and the sensor array support comprises a fixing unit so that a semi-hermetic space is formed between the sample extraction plate and the sensor array support.

### BRIEF DESCRIPTION OF THE DRAWINGS

The above and other features and advantages of the present invention will become more apparent by describing in detail exemplary embodiments thereof with reference to the attached drawings in which:

FIG. 1 is a block diagram of an electronic nose sensor system including a personal digital assistant (PDA), according to an embodiment of the present invention;

FIG. 2 is a photograph showing an appearance of the electronic nose sensor system including the PDA of FIG. 1, according to an embodiment of the present invention;

FIGS. 3A and 3B are photographs showing a front side and a rear side of a sensor array according to an embodiment of the present invention;

FIG. 4 is a cross-sectional view of a unit sensor in the sensor array illustrated in FIG. 3A;

FIGS. 5A through 5E are cross-sectional views for explaining procedures of manufacturing a unit sensor, according to an embodiment of the present invention;

FIG. 6 illustrates chemical formulas of high polymers and additives used in the 8-channel sensor array shown in FIG. 3A;

FIG. 7 is a photograph showing a sensor module attached to the PDA of FIG. 2, according to an embodiment of the present invention;

FIG. 8 is a circuit diagram of a voltage dividing circuit used as a resistance detecting circuit in an embodiment of the present invention;

FIG. 9 is a circuit diagram of a circuit for driving fine heaters shown in FIG. 3B;

FIG. 10 is a graph showing resistance changes with temperature of the fine heaters of FIG. 3B, according to an embodiment of the present invention;

FIGS. 11 and 12 are graphs showing changes in power consumption with the operation temperature of the fine heaters shown in FIG. 3B and time;

FIG. 13 is a graph showing ethanol sensing resistance (Ω) of a sensor array formed using carbon black-ethyl cellulose (EC);

FIG. 14 is a graph illustrating relationship between a sensing resistance (Ω) of the carbon black-EC sensor and a measuring time according to operation temperatures;

FIG. 15 is a graph showing toluene sensing resistance of first through fourth sensors according to an embodiment of the present invention;

FIG. 16A is a graph showing PCA results of eight organism molecules (ethanol, methanol, 2-prophanol, benzene, toluene, heptane, hexane, and cyclohexane), and FIG. 16B is an expanded graph showing PCA result data excluding the alcohol compounds in FIG. 16A;

FIG. 17 is a cross-sectional view for explaining a method of extracting a sample of an electronic nose sensor array;

FIG. 18A is a photograph showing a sensor array to which a sample extraction plate is attached and a PDA to which the sensor array is mounted and which displays resistances varying with a sample measurement result;

FIG. 18B is a photograph showing the PDA with the sensor array from which the sample extraction plate is separated;

FIGS. 19 through 21 are graphs illustrating sensing sensitivities of the first through eighth sensors in FIG. 6, each made of polymers and additives shown, with respect to oils extracted from the mint, lavender, and eucalyptus, respectively; and

FIG. 22 is a graph showing patterns of sensing sensitivities for the oils extracted from mint, lavender, and eucalyptus in a three-dimensional PCA space.

### DETAILED DESCRIPTION OF THE INVENTION

The present invention will now be described more fully with reference to the accompanying drawings, in which exemplary embodiments of the invention are shown. The invention may, however, be embodied in many different forms and should not be construed as being limited to the embodiments set forth herein; rather, these embodiments are provided so that this disclosure will be thorough and complete, and will fully convey the concept of the invention to those skilled in the art. In the drawings, the thicknesses of layers and regions are exaggerated for clarity. It will also be understood that when a layer is referred to as being “on” another layer or substrate, it can be directly on the other layer or substrate, or intervening layers may also be present. Like reference numerals in the drawings denote like elements, and thus their description will be omitted.

In the embodiments of the present invention, a chip-shaped electronic nose sensor array in which a plurality of electronic nose sensors, each of which is fabricated by forming a detecting film consisting of conductive particles and non-conductive organic material on a polymer substrate, are arranged will be described. Each of the sensors arranged in the sensor array is referred to as a ‘unit sensor’. In addition, the embodiments of the present invention will be applied to an electronic nose sensor system in which the electronic nose sensor array is attached to a personal information terminal.

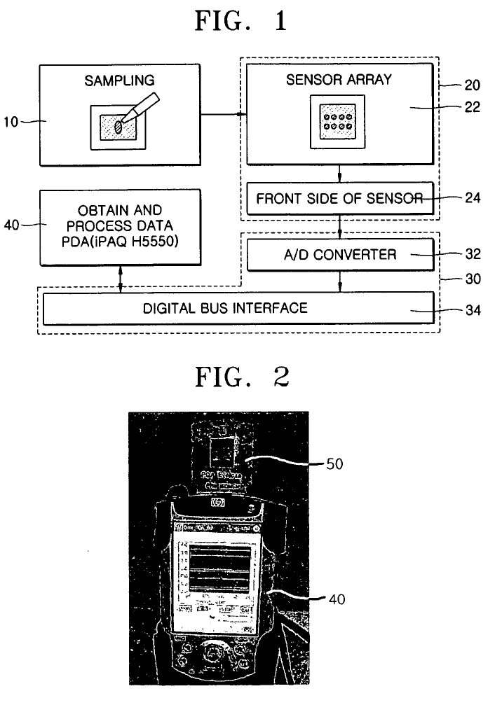

FIG. 1 is a block diagram of an electronic nose sensor system including a personal information terminal 40 such as a personal digital assistant (PDA). FIG. 2 is a photograph showing an appearance of the electronic nose sensor system including the PDA of FIG. 1.

Referring to FIGS. 1 and 2, the sensor system is divided into four sections, which are hardware 10 for extracting a sample, an electronic nose sensing module 20 including an electronic nose sensor array 22, an electronic circuit board 30 for digitalizing measured analog data and then transmitting the data to the personal information terminal 40, and the personal information terminal 40 for storing and analyzing the transmitted data in real-time. The electronic circuit board 30 is divided into an A/D converter 32 and a digital bus interface 34. The A/D converter 32 is connected to a front side 24 of the sensing module 20, and the interface 34 is connected to the electronic circuit board 30.

In the present embodiment, the personal information terminal 40 is a PDA, model DAQ 6062 manufactured by NI Company. Except for the personal information terminal 40, hardware elements, which will be described later, are manually fabricated. A sensor array 50 is connected to the personal information terminal.

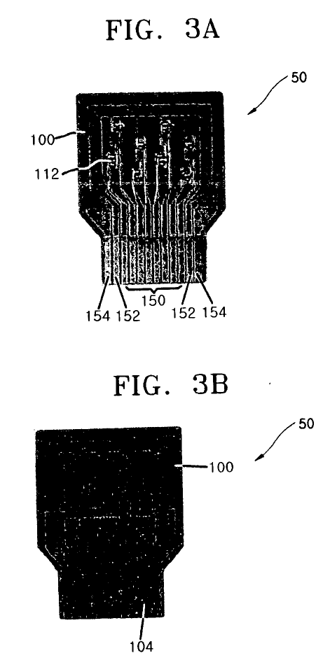

FIGS. 3A and 3B are photographs showing a front side and a backside of the sensor array 50 of FIG. 2 according to an embodiment of the present invention. Specifically, FIG. 3A shows the front side of the sensor array 50 on which 8-channel sensors connected to sensing electrodes 112 and other components are arranged, and FIG. 3B shows the backside of the sensor array 50 on which fine heaters 104 are arranged.

Exposed metal lines 150, 152, and 154 in FIG. 3A are electrical contact pads required for measurement of the sensor array 50 and control of the heaters 104. Each of unit sensors of 8-channel includes signal lines 150 and a ground line 152. The heaters 104 penetrating a polymer substrate 100 are connected to power pads 154 on the front side. Accordingly, eight lines on the front side are the signal lines 150 for measuring a sensing signal of the sensor, two lines next to the eight signal lines 150 are the ground lines 152 which are commonly connected to each of the sensor arrays, and power pads 154 disposed at each edge of the sensor array 50 supply power to the heaters 104.

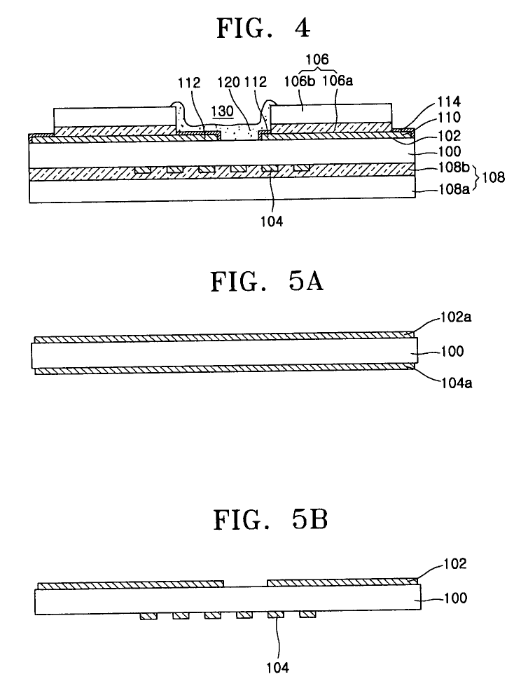

FIG. 4 is a cross-sectional view of the unit sensor forming the sensor array illustrated in FIG. 3A.

Referring to FIG. 4, upper metal lines 102 and lower metal lines 104 are deposited on a top surface and a bottom surface of the polymer substrate 100, respectively. Both ends of the upper metal line 102 include contact pads 110 for connecting a sensing electrode 112 to an external electronic circuit (not shown). The lower metal lines 104 are conductive metal lines for heaters 104. Portions of the upper and lower metal lines 102 and 104 which are not necessarily to be exposed are covered with an upper protecting layer 106 and a lower protecting layer 108, respectively. The upper protecting layer 106 and the lower protecting layer 108 include a polymer adhesive layers 106a and 108a and protective films 106b and 108b, respectively. A portion of the upper metal line 102 exposed by the upper protecting layer 106 is an electrode pad 110 for electrically connecting the sensing electrode 112 covered with a sensing layer 120 to the outside. The sensing electrode 112 and the electrode pad 110 are processed to be in a desired form and then aligned and attached to the substrate 100. The exposed sensing electrode 112 and the electrode pad 110 may include metal plating layers 114 formed on the surface of each of them to improve electrical contact. Subsequently, the sensing layer 120 is formed on the sensing electrode 112 to complete the unit sensor.

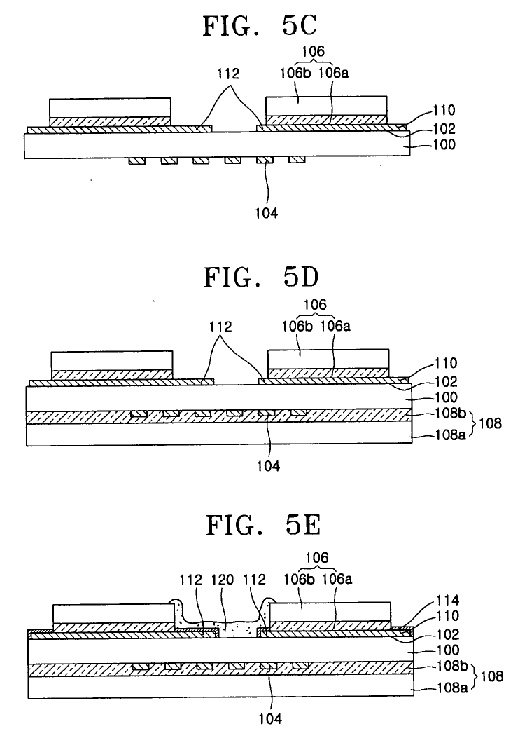

FIGS. 5A through 5E are cross-sectional views for explaining procedures of manufacturing a unit sensor, according to an embodiment of the present invention. The procedures of manufacturing the unit sensor are based on the manufacturing processes for a flexible printed circuit board (FPCB). In the present embodiment, the FPCB manufacturing processes are partially modified to minimize the interaction between low power required by a sensor array chip, materials for the unit sensor and a substrate.

Referring to FIG. 5A, upper and lower metal line material layer 102a and 104a, for example, copper layers, are formed on both sides of the polymer substrate 100. The polymer substrate 100 may be composed of a polymer material, for example, polyimide, polyester, polyurethane, and glass epoxy. A thickness of the polymer substrate 100 may be between 10 and 200 μm.

In the general FPCB manufacturing processes, a copper layer is deposited as a copper film on a substrate. However, in the present embodiment, to reduce a thickness of a sensor array, remove interaction between organic solvents and an organic adhesive layer, and minimize heat loss, copper thin layers are directly deposited on both sides of the polymer substrate 100. To enhance adhesion between the polymer substrate 100 and the copper layers, nickel layers of a thickness of about 0.1 μm are formed on both sides of the polymer substrate 100 using sputtering, and then the copper layers are formed to be of a thickness of between 2 and 20 μm using an electric chemical method. Materials for increasing adhesion between the polymer substrate 100 and the copper layers may be chrome Cr or titanium Ti, besides of the nickel Ni.

Referring to FIG. 5B, an upper metal line 102 and a lower metal line 104 are formed by patterning the upper and lower metal line material layers 102a and 104a formed on both sides of the substrate 100, respectively. In this case, the lower metal line 104 is referred to as a fine heater. The patterning process may be performed using screen printing or photolithography which are widely used in the FPCB manufacturing processes. The process of patterning on the polymer substrate 100 has an advantage of using a roll-by-roll method.

Ends of the upper metal line 102 are formed into the sensing electrode 112 and the electrode pad 110 in a subsequent process. The upper metal line 102 can be manufactured in a variety of shapes. In the present embodiment, the upper metal lines 102 may be interlaced with each other, each having a comb shape, the sensing electrode 112 as illustrated in FIG. 3A. A distance between the sensing electrodes 112 is about 30 μm, and a sensing region 130 has a circular shape having a diameter of about 2 mm. Each of the fine heaters 104 has a width of about 100 μm, and a distance between the fine heaters 104 is about 200 μm.

Referring to FIG. 5C, the upper protecting layer 106 is formed to cover the upper metal line 102. The upper protecting layer 106 prevents electrical interference or damage due to exposure of the metal line 102 to the outside. Both ends of the upper metal line 102 are exposed by the upper protecting layer 106 so that the sensing electrode 112 and the electrode pad 110 are formed. The upper protecting layer 106 is formed by attaching a polymer film to an adhesive layer 106a. Additionally, the upper protecting layer 106 is processed to have a desired shape, and then aligned and attached to the polymer substrate 100. The adhesive layer 106a may be an organic solvent in an acryl group or an epoxy group, and the polymer film may be composed of a polymer material, for example, polyimide, polyester, and polyurethane. A thickness of the polymer film 106b may be between 10 and 200 μm.

Referring to FIG. 5D, the lower protecting layer 108 is attached to the substrate 100 to completely block the fine heaters 104 from the outside. The lower protecting layer 108 is made of the same material and is manufactured by the same method as the upper protecting layer 106. However, since on a pad region (not shown), a physical coupling exists for electrical connection, a reinforcement board may be further attached to support the pad region. A glass epoxy board, a paper phenol board, a polyimide board, or a polyester board of a thickness of several hundreds gem is widely used for the reinforcement board.

Meanwhile, to reduce power consumption of the fine heaters 104, the lower protecting layer 108 on a middle section of the sensor array where the heaters 104 are concentrated may be removed. The heaters 104 of the sensor array from which the lower protecting layer 108 is removed are separated from the outside by a device, for example, a PDA, in which the sensor array is mounted.

Referring to FIG. 5E, the sensing electrode 112 and the electrode pad 110 which are exposed by the upper protecting layer 106 are plated with the metal plating layer 114. The plating process prevents the exposed sensing electrode 112 and electrode pad 110 from oxidizing or lowering their performances due to the external environment. Solder plating and gold plating are widely used for the plating process. The solder plating is useful when an electrical connection is formed using lead. The gold plating is based on the high conductivity of gold and good resistance to chemical reactions. Thus, in the present embodiment, the gold plating is desirably applied. A thickness of a plate may be between 1 and 30 μm. A very thin additional adhesive metal, for example, nickel Ni, is formed between the sensing electrode 112 and electrode pad 110 and the plating layer 114 to increase the adhesion therebetween. The sensing layer 120 is formed to cover the exposed surface of the metal plating layer 114 in the sensing region 130.

The sensing layer 120 generally detects a mass increased by absorbed chemical species or the electric conductivity. A sensor including a sensing layer 120 that detects the mass is a QCM sensor or a SAW sensor, and a sensor including a sensing layer that detects the electric conductivity is an oxide semiconductor sensor, a conductive polymer sensor, or a conductive particle-organic compound sensor.

The sensor (hereinafter, referred to as a conductive particle-organic compound sensor) using a conductive particle-organic compound as a sensing layer is very stable to the external environment, can be manufactured in a variety of shapes, and is suitable for a compact electronic nose sensor. The conductive particle-organic compound sensor is formed by distributing electric conductive particles onto an organic medium that is an electrical isolator. At this moment, if chemical species to be analyzed permeate the sensing layer 120 and affect the electric conductivity when a path of the electric conductivity is limited by the conductive particles, the resistance of the sensor is changed. As a specific example, there is a carbon black-polymer compound sensor which is composed us conductive carbon black particles and insulating polymers.

In the present embodiment, a sensor array using conductive carbon black particles and non-conductive polymers is employed. More specifically, to produce a sensor array for analyzing various chemical species, the sensor is fabricated using various kinds of non-conductive polymers. Moreover, properties of the non-conductive polymers are changed by using a hybrid polymer in which different non-conductive polymers are blended or adding an additive that is a monomolecular organic material. Typical non-conductive polymers are listed in Table 1, and typical additives are dioctylphthalate (DOP) and di(ethyleneglycol) dibenzoate (DGD).

TABLE 1

| No. | ID | Chemical name |
|---|---|---|
| 1 | PS | Polystyrene |
| 2 | PMMA | Poly(methly methacrylate) |
| 3 | PVP | Polyvinylpyrrolidone |
| 4 | PVA | Poly(vinyl acetate) |
| 5 | PEO | Poly(ethylene oxide) |
| 6 | PMS | Poly(-methylstyrene) |
| 7 | PVPh | Poly(4-vinylphenol) |
| 8 | PSF | Polysulfone |
| 9 | PCL | Polycaprolactone |
| 10 | P4MS | Poly(4-methylstylene) |
| 11 | PS-MMA | Poly(stylene-co-methylmethacrylate) |
| 12 | PE-VA | Poly(ethylene-co-vinylacetate) |
| 13 | PVC-AN | Poly(vinylidene chloride-co-acrylonitrile) |
| 14 | PS-AA | Poly(styrene-co-allyl achohol); |
| | | hydroxyl 5.8-7% |
| 15 | PMVE&MA | Poly(methyl vinyl ether-alt-maleic anhydride) |
| 16 | PS-BD | Poly(styrene-co-butadiene); 45 wt % styrene |
| 17 | PBC | Poly(bisphenol A carbonate) |
| 18 | PBD | Poly(butadiene) |
| 19 | P4VP | Poly(4-vinyl pyridine) |
| 20 | PS-MA | Poly(styrene-co-maleic anhydride); 14% MA |
| 21 | PS-AN | Poly(styrene-co-acrylonitrile); 25% AN |
| 22 | PE-AA | Poly(ethylene-co-acrylic acid); 20% AA |
| 23 | PVC-VA | Poly(vinyl chloride-co-vinyl acetate); 10% VA |
| 24 | PVB-VA-VA | Poly(vinyl butyral)-co-vinyl alcohol-co-vinyl |
| | | acetate |
| 25 | PVS | Poly(vinyl stearate) |
| 26 | EC | Ethyl cellulose |
| 27 | PS&IP&PS | Polystrene-black-polyisoprene-black-polystrene |
| 28 | HPC | Hydroxypropyl cellulose |
| 29 | CA | Cellulose acetate |
| 30 | PEG | Poly(ethylene glycol) |

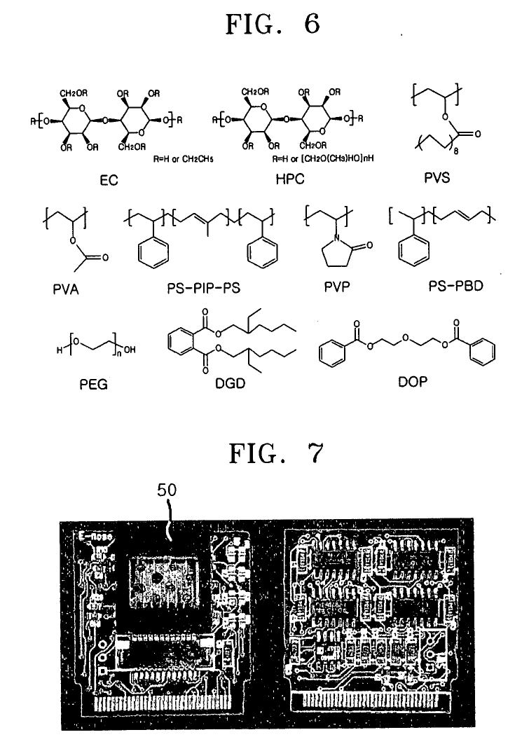

FIG. 6 illustrates chemical formulas of high polymers and additives used in the 8-channel sensor array shown in FIG. 3A. Eight non-conductive high polymers EC, HPC, PVS, PVA, PS-PIP-PS, PVP, PS-PBD, and PEG are used for a first sensor 1 through an eighth sensor 8, respectively, and the remaining DGQ and DOP are the additives. For convenience of explanation, in the sensor array of FIG. 3, the sensors are sequentially numbered from left 1 to right 8. In this case, the second sensor 2 and the fourth sensor 4 are fabricated by adding DGD thereinto and the sixth sensor 6 is fabricated by adding DOP thereinto.

To form the sensing layer 120, first, the non-conductive polymer is dissolved in an organic solvent. In this case, the organic solvent is typically carbon tetrachloride, THF, benzene, carbon dichloride, toluene, or ethanol. Furthermore, to effectively dissolve the high polymer, the organic solvent may be agitated while being heated at a temperature of about 50° C. Next, carbon black is inserted into the polymer solution, and then an impact is applied thereto by ultrasonic waves for about 10 minutes to distribute the carbon black particles evenly through the solution. A quantity of the solvent is about 10 ml, the carbon black is about 20 mg, and the polymer is about 80 mg. The quantity of the carbon black may be of between 10 and 30% of the total weight of the non-conductive polymers and the carbon black particles. The sensing layer 120 having a resistance of between 1 k and 10M has a good sensing characteristic. When the additive is used, the total weight of the polymer and the additive may be about 80 mg, and the additive is added in amounts of between 10 and 60 percent by weight.

A method of forming the sensing layer 120 using a polymer compound solution includes dispensing, in which the solution is dropped onto the sensing electrode 112 using a micro pipette, dipping, in which the substrate 100 including the sensing electrode 112 is immersed into the solution, then taken out from the solution and dried, or spin-coating in which the solution is dropped onto the sensing electrode 112 and then the substrate 100 is rotated. The sensor array according to the present embodiment may be manufactured using the dispensing method. The sensing layer 120 in the present embodiment operates at a normal temperature.

To drive a sensor array, an interface circuit that detects changes in the electric conductivity due to the addition of an analyte and a circuit and a device that apply power and control a power source of the heaters 104 are required. FIG. 7 is a photograph showing a sensor module attached to the PDA of FIG. 2, according to an embodiment of the present invention. Referring to FIG. 7, the sensor module includes a sensor array (left) and an interface circuit (right). The sensor array is manufactured using a flexible polymer substrate. The interface circuit can simultaneously transmit signals generated at the same time by a plurality of channels, for example, the eight channels shown in FIG. 3A.

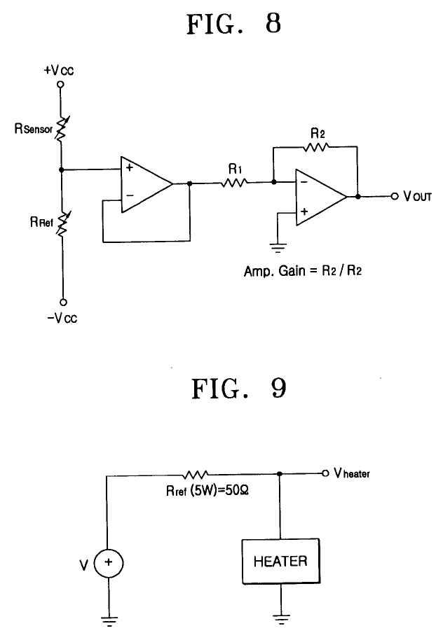

FIG. 8 is a circuit diagram of a voltage dividing circuit used as a resistance detecting circuit used in the present embodiment. To minimize an electrical interference between the sensor and the voltage dividing circuit, an OP amp is connected to an input terminal of the sensor to amplify a signal voltage, if necessary.

FIG. 9 is a circuit diagram of a circuit for driving the fine heaters 104 shown in FIG. 3B. The temperature is detected via resistance changes since current through the heaters 104 varies with the resistance thereof.

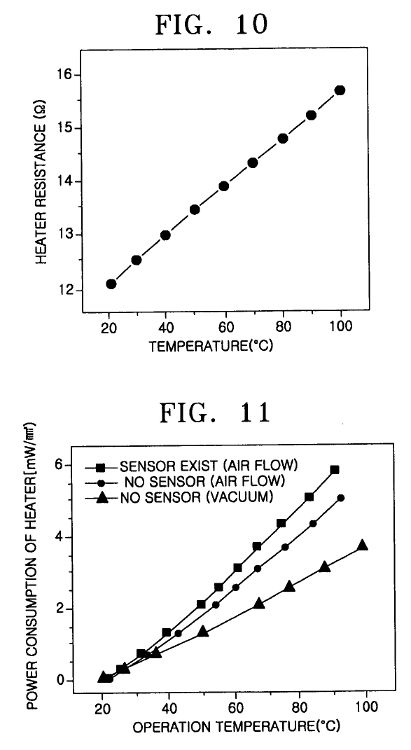

FIG. 10 is a graph showing resistance changes with temperature of the fine heaters 104 according to an embodiment of the present invention. The fine heaters 104 are put in an oven and then the resistance is measured. As illustrated, the resistance linearly increases as the temperature increases. In the present embodiment, a temperature coefficient of resistance (TCR) of the fine heaters 104 is 37×10⁻⁴° C.⁻¹. Thus, it can be known that copper layers can be used as the fine heaters 104.

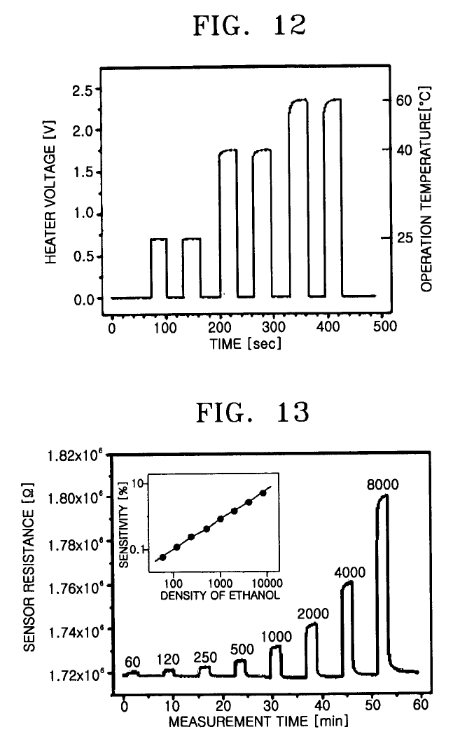

FIG. 11 is a graph showing changes in power consumption with the operation temperature of the fine heaters 104 shown in FIG. 3B. FIG. 12 is a graph of a voltage of the heaters 104 versus time. As shown in FIG. 11, power consumption changes according to vacuum occurrence, presence of a sensor, and a change of operation temperature. The fine heaters 104 of the sensor are not covered with the lower protecting layer 108, and their power consumption is about 1.5-3 mW/mm at an operation temperature of 50° C., even though there are some differences between the measured values according to vacuum occurrence and a presence of a sensor. Referring to FIG. 12, the sensor array reaches the operation temperature and can be controlled, to reach the required temperature. The fine heaters 104 are suitable for a sensor array of an organic group, which operates at relatively low temperature.

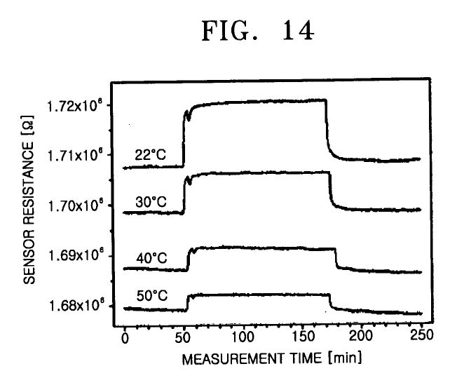

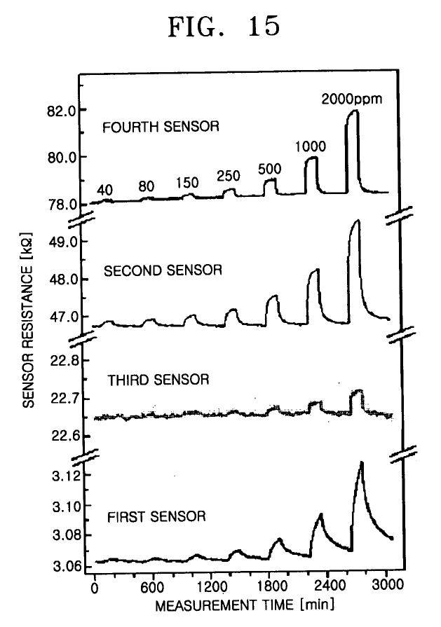

FIG. 13 is a graph showing ethanol sensing resistance (Ω) of a sensor array formed using carbon black-ethyl cellulose (EC); The obtained sensitivity can be converted from a change of the sensed resistance (Ω). The density of ethanol increases with time. An ethanol gas at constant density is diluted in the dry air for about two minutes using a flow injection sample extracting method and transmitted to a sensor array. A graph inside the graph of FIG. 13 shows an intensity of the sensing resistance (sensitivity) according to the density of ethanol. Referring to FIG. 13, a sensing resistance of a black-EC sensor is linearly changed within a wide density range area (50-8000 ppm) of ethanol. Furthermore, the electric conductivity of the sensor, that is, the resistance of the sensor is reversibly and quickly changed according to injection and removal of ethanol.

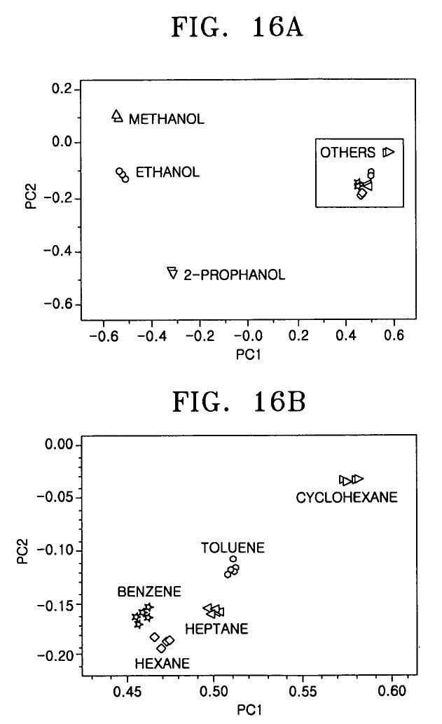

FIG. 14 is a graph of a sensing resistance (Ω) of the carbon black-EC sensor versus a measuring time for different operation temperatures. An initial resistance and a sensing resistance are reduced as the operation temperature increases. Although the reduction of the initial resistance is not measured with respect to all of the operation temperatures, the reduction of the initial resistance of the sensor is a general phenomenon. The sensing resistance is reduced because a thermodynamic equilibrium between a sample and a material forming the sensor moves in such a direction that an amount of analyte included in the material is gradually reduced as the temperature increases.

FIG. 15 is a graph showing toluene sensing resistance of first through fourth sensors according to an embodiment of the present invention. The sensing resistance is linearly increased according to density of the toluene, but the changes in the sensing resistance of the first through fourth sensors are different from each other.

To determine an unknown sample using a sensor array, a pattern recognition program using a medium variable extracted from a sensing resistance change (sensing sensitivity) curve of each sensor is executed. In the present invention, a pattern recognition program is executed using resistance change rate as the medium variable.

A principal component analysis (PCA) method is the most typical and simplest method of various pattern recognition programs which have been developed so far. The PCA method displays multi-dimensional sensing pattern vectors on new coordinate axes via linear conversion of vectors to most effectively represent the sensing pattern vectors according to a predetermined analysis. That is, by processing a multi-dimensional matter in a lower dimension, the multi-dimensional matter is easily visualized or an important part of the matter is calculated, thereby reducing the calculation load.

FIG. 16A is a graph showing PCA results of eight organism molecules (ethanol, methanol, 2-prophanol, benzene, toluene, heptane, hexane, and cyclohexane), and FIG. 16B is an expanded graph showing PCA result data excluding alcohol compounds in FIG. 16A. Referring to FIGS. 16A and 16B, the alcohol compounds are relatively well distinguished from each other, and the remaining samples are distinguished from each other, not clearly, but enough (see FIG. 16A). By utilizing a group of data obtained using the PCA method (referred to as a reference measurement), a sample, which is one of the eight compounds (organism molecules), can be determined.

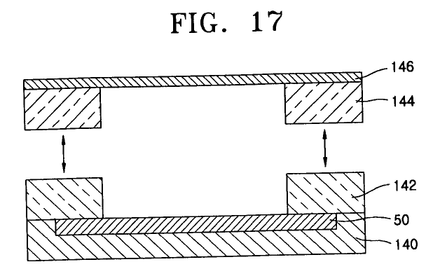

FIG. 17 is a cross-sectional view for explaining a method of extracting a sample of an electronic nose sensor array 50, according to an embodiment of the present invention. The sensor array 50 manufactured with a polymer substrate is disposed in a sensor array support 140 formed of metal and fixed to a fixing unit 142 such that a sensing electrode 112 in FIG. 3A is exposed to the outside. A sample is extracted by a sample extraction plate 146 attached to a side of a sample plate support 144, the center of which is empty. The sample extraction plate 146 into which liquid can permeate is manufactured using filter paper made of a cellulose material.

To extract a sample, first, a drop of a liquid sample to be extracted is put on an analysis plate 146 using a pipette. The sample is absorbed into the analysis plate 146 and the remaining sample that is not absorbed into the analysis plate 146 is vaporized into the air. An initial state is recorded in a PDA using the electronic nose sensor array 50 attached to the PDA. After a predetermined period of time passes, the analysis plate 146 is attached to the sensor array support 140. That is, an airtight space is produced by the analysis plate 144 and the fixing unit 142. Then, the sample is measured for a predetermined period of time, and the analysis plate 146 is then separated from the sensor array support 140. After a predetermined period of time passes for which a sensing signal, for example, resistance, returns to its original state, the measurement is finished.

In the present invention, oils extracted from mint, lavender, and eucalyptus were analyzed. In the sample analysis method used for the present invention, a vapor of a liquid sample, which is gradually evaporated from the sample extraction plate 146 after the liquid sample is absorbed into the sample extraction plate 146, was analyzed. According to the method, a semi-hermetic space is formed by sealing around the sample extraction plate 146. In the semi-hermetic space, the density of a sample to be extracted does not significantly vary over time. This is because the semi-hermetic space allows the evaporation speed of vapor to be similar to the speed at which the sample gasified in the semi-hermetic space escapes to the outside due to a difference between the densities between the inside and the outside of the sample extraction plate 146. When the sample was measured without the semi-hermetic space, sensing sensitivity depended on the external environment, and thereby could not reach a constant equilibrium state.

The sample analysis method using the semi-hermetic space is less reliable than a sample analysis method using a hermetic space or a flow injection analysis method, but more suitable for a compact electronic nose sensor array attached to a personal information terminal. It was experimentally observed that the oils extracted from mint, lavender, and eucalyptus were successfully analyzed according to the sample analysis method using the semi-hermetic space.

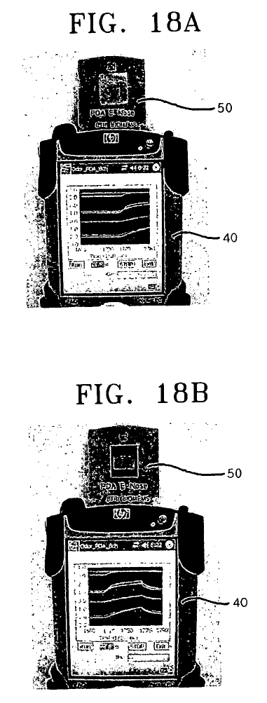

FIG. 18A is a photograph showing a sensor array 50 to which a sample extraction plate 146 is attached and a PDA 40 to which the sensor array 50 is mounted and which displays resistances varying according to a sample measurement result. FIG. 18B is a photograph showing the PDA 40 with the sensor array 50 from which the sample extraction plate 146 is separated.

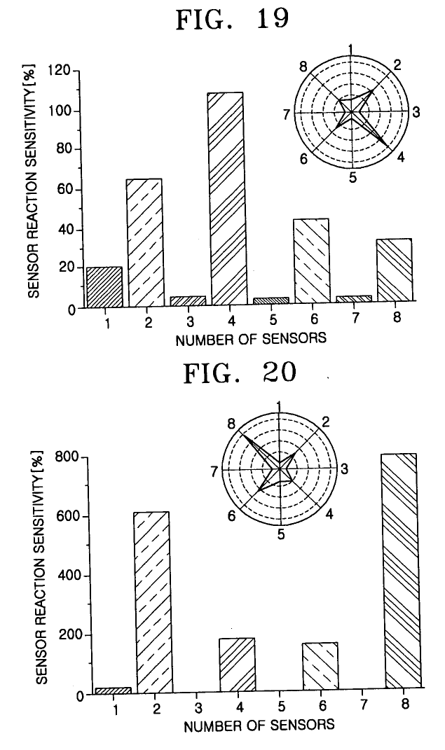

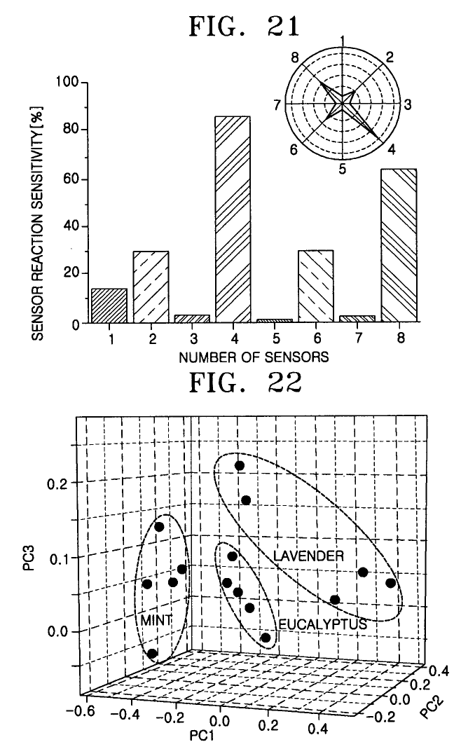

FIGS. 19 through 21 are graphs illustrating sensing sensitivities of the first through eighth sensors, each made of polymers and additives shown in FIG. 6, with respect to oils extracted from the mint, lavender, and eucalyptus, respectively. The sensing sensitivities of respective sensors denote the maximum rates of resistance change thereof, and are illustrated as a bar graph and a circle shape. Referring to FIGS. 19 through 21, the sensing sensitivities are different according to the kind of oils. For instance, in the case of the mint (see FIG. 19), the fourth sensor has the strongest sensing sensitivity, and the third, fifth, and seventh sensors have weak sensing sensitivities. The different results of the sensing sensitivity indicate the PCA method that is the pattern recognition program is available for determination of a sample.

FIG. 22 is a graph showing patterns of sensing sensitivities for the oils extracted from mint, lavender, and eucalyptus in a three-dimensional PCA space. Each sample was measured repeatedly five times. As shown in FIG. 12, there are borders between the measurement results of the same oil and the measurement results of the other oils to be distinguished from each other. While the measurement results of the mint and eucalyptus oils are not much affected by time, the sensing sensitivity pattern of the lavender oil varies with time. The movement of the pattern indicates the amounts of chemical species in the sample extraction plate 146 are greatly changed over time because the evaporation speeds of various compounds are different from each other according to their chemical species. However, even in the case of the lavender, there was no great difference between the measurement results obtained within an hour after the sample is extracted from the lavender oil. To determine the sample more accurately, careful controls are required to conduct an experiment on an unknown analyte under the same condition as the previous experiments.

According to the present invention, an electronic nose sensor comprises a sensor array manufactured using a polymer substrate, and thus mass-production of the electronic nose is possible. Furthermore, fine heaters are formed on a side of the polymer substrate, and therefore measurement can be performed at a constant temperature. Since a mixture of conductive polymer and non-conductive polymers is used as a sensing film, the sensor array can be driven at a low temperature and micro-miniaturization of the sensor array is possible.

Moreover, by using a sample extraction structure including a liquid permeative film, a sample is easily extracted by hand. In addition, multi-variable measurement data is obtained and processed using a sensor array attached to a personal information terminal, and thus, a compact electronic nose sensor system available for analyzing chemical species in real-time can be implemented.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. An electronic nose sensor array comprising:
a flat-panel type polymer substrate;
a plurality of sensing films which is formed on a first side of the polymer substrate and react to chemical species to be analyzed, thereby changing their electric resistances; and
a plurality of sensing electrodes, each of which contacts both ends of each of the sensing films and senses a change of one of the electric resistances.

2. The electronic nose sensor array of claim 1, wherein the polymer substrate is at least one selected from polyimide, polyester, and glass epoxy.

3. The electronic nose sensor array of claim 1, wherein the sensing film is made of a mixture of conductive particles and non-conductive organic material.

4. The electronic nose sensor array of claim 2, wherein the sensing film is made of a mixture of conductive carbon black and polymer.

5. The electronic nose sensor array of claim 3, wherein the non-conductive organic material is at least one selected from Polystyrene, Poly(methyl methacrylate), Polyvinylpyrrolidone, Poly(vinyl acetate), Poly(ethylene oxide), Poly(-methylstyrene), Poly(4-vinylphenol), Polysulfone, Polycaprolactone, Poly(4-methylstylene), Poly(stylene-co-methylmethacrylate), Poly(ethylene-co-vinylacetate), Poly(vinylidene chloride-co-acrylonitrile), Poly(styrene-co-allyl alcohol), Poly(methyl vinyl ether-alt-maleic anhydride), Poly(styrene-co-butadiene), Poly(bisphenol A carbonate), Poly(butadiene), Poly(4-vinyl pyridine), Poly(styrene-co-maleic anhydride), Poly(styrene-co-acrylonitrile), Poly(ethylene-co-acrylic acid), Poly(vinyl chloride-co-vinyl acetate), Poly(vinyl butyral)-co-vinyl alcohol-co-vinyl acetate, Poly(vinyl stearate), Ethyl cellulose, Polystrene-black-polyisoprene-black-polystrene, Hydroxypropyl cellulose, Cellulose acetate, and Poly(ethylene glycol).

6. The electronic nose sensor array of claim 1, wherein the sensing film further comprises an additive to change characteristics of the non-conductive organic material.

7. The electronic nose sensor array of claim 6, wherein the additive is dioctylphthalate or di(ethyleneglycol) dibenzoate.

8. The electronic nose sensor array of claim 1, wherein the sensing electrodes are parts of an upper metal line exposed by an upper protecting layer.

9. The electronic nose sensor array of claim 1, wherein a fine heater is disposed on a second side of the polymer substrate.

10. The electronic nose sensor array of claim 9, wherein a lower protecting layer covers the fine heater to block the fine heater from the outside.

11. The electronic nose sensor array of claim 8 or 10, wherein each of the upper protecting layer and the lower protecting layer is made of at least one or more selected from polyimide, polyester, and glass epoxy.

12. A electronic nose sensor system comprising:
a electronic nose sensor array; and
a personal digital assistant to which the electronic nose sensor array is attached and which obtains data measured by the electronic nose sensor array in real-time and processes the data using a pattern recognition program,
wherein the electronic sensor array comprises:
a flat-panel type polymer substrate;
a plurality of sensing films which is formed on a side of the polymer substrate and react to chemical species to be analyzed, thereby changing their electric resistances; and
a plurality of sensing electrodes, each of which contacts both ends of each of the sensing films and senses a change of one of the electric resistances.

13. The electronic nose sensor system of claim 12, wherein the pattern recognition program is a principal component analysis method.

14. The electronic nose sensor system of claim 12, wherein the personal digital assistant includes an electronic circuit board that digitalizes and transmits the measured data to the personal digital assistant.

15. The electronic nose sensor system of claim 14, wherein the electronic circuit board comprises an analog/digital convert and a digital bus interface.

16. The electronic nose sensor system of claim 12, wherein the electronic nose sensor array further comprises hardware for extracting a sample.

17. The electronic nose sensor system of claim 16, wherein the hardware for extracting sample includes a liquid permeative film which allows the sample to evaporate and causes the concentration gradient.

18. A method of manufacturing an electronic nose sensor array, the method comprising:
preparing a polymer substrate;
forming an upper metal line on a side of the polymer substrate, the upper metal line including a plurality sensing electrodes and contact pads;
forming a plurality of heaters on the opposite side of the polymer substrate; and
forming a plurality of sensing films made of a mixture of conductive particles and a non-conductive material.

19. The method of claim 18, wherein the upper metal line and the heaters are formed using an electric-chemical method.

20. The method of claim 18, wherein the sensing electrodes are interlaced with each other, each having a comb shape.

21. The method of claim 18, further comprising:
forming an upper protecting layer on the upper metal line such that the sensing electrodes and the contact pads are exposed.

22. The method of claim 18, further comprising:
forming a lower protecting layer that covers the heaters to block the heaters from the outside.

23. The method of claim 18, wherein each of the sensing films is made of a mixture of conductive carbon black and polymer.

24. The method of claim 18, wherein the non-conductive organic material is at least one selected from Polystyrene, Poly(methyl methacrylate), Polyvinylpyrrolidone, Poly(vinyl acetate), Poly(ethylene oxide), Poly(-methylstyrene), Poly(4-vinylphenol), Polysulfone, Polycaprolactone, Poly(4-methylstylene), Poly(stylene-co-methylmethacrylate), Poly(ethylene-co-vinylacetate), Poly(vinylidene chloride-co-acrylonitrile), Poly(styrene-co-allyl alcohol), Poly(methyl vinyl ether-alt-maleic anhydride), Poly(styrene-co-butadiene), Poly(bisphenol A carbonate), Poly(butadiene), Poly(4-vinyl pyridine), Poly(styrene-co-maleic anhydride), Poly(styrene-co-acrylonitrile), Poly(ethylene-co-acrylic acid), Poly(vinyl chloride-co-vinyl acetate), Poly(vinyl butyral)-co-vinyl alcohol-co-vinyl acetate, Poly(vinyl stearate), Ethyl cellulose, Polystrene-black-polyisoprene-black-polystrene, Hydroxypropyl cellulose, Cellulose acetate, and Poly(ethylene glycol).

25. The method of claim 18, wherein the sensing film includes an additive to change characteristics of the non-conductive organic material.

26. The method of claim 25, wherein the additive is dioctylphthalate or di(ethyleneglycol) dibenzoate.

27. A method of analyzing a sample using an electronic nose sensor array, the method comprising:
extracting a sample using hardware for extracting the sample;
starting measuring the sample using a personal digital assistant employing a pattern recognition program;
attaching the hardware for extracting the sample to a sensor array support;
saturating reactions in the electronic nose sensor array;
separating the hardware for extracting the sample from the sensor array support; and
initializing the reactions in the electronic nose sensor array,
wherein the electronic nose sensor array comprises:
a flat-panel type polymer substrate;
a plurality of sensing films which is formed on a side of the polymer substrate and react to chemical species to be analyzed, thereby changing their electric resistances; and
a plurality of sensing electrodes, each of which contacts both ends of each of the sensing films and senses a change of one of the electric resistance.

28. The method of claim 27, wherein the hardware for extracting the sample comprises a sample extraction plate formed by a liquid permeative film and a sample plate support, and the sensor array support comprises a fixing unit so that a semi-hermetic space is formed between the sample extraction plate and the sensor array support.
